(19) United States
(12) Patent Application Publication
(10) Pub. No.: US 2016/0163946 A1
(43) Pub. Date: Jun. 9, 2016

(54) THERMOELECTRIC GENERATOR

(71) Applicants: COMMISSARIAT À L'ENERGIE ATOMIQUE ET AUX ENERGIES ALTERNATIVES, Paris (FR); HOTBLOCK ONBOARD, Grenoble (FR)

(72) Inventors: Sébastien VESIN, Toulon (FR); Joël DUFOURCQ, Puyoo (FR)

(73) Assignees: COMMISSARIAT À L'ÉNERGIE ATOMIQUE ET AUX ENERGIES ALTERNATIVES, Paris (FR); HOTBLOCK ONBOARD, Grenoble (FR)

(21) Appl. No.: 14/906,159

(22) PCT Filed: Jul. 15, 2014
(86) PCT No.: PCT/FR2014/000164

§ 371 Date: Jan. 19, 2016

(30) Foreign Application Priority Data
Jul. 17, 2013 (FR) 1301694

(51) Int. Cl. H01L 35/30; H01L 35/04; H01L 35/34

(52) U.S. Cl. CPC H01L 35/30; H01L 35/34; H01L 35/04

(57) ABSTRACT

The thermoelectric device includes a first duct housed in a second duct in tightly sealed manner. The first and second ducts extend along a longitudinal axis. The device further includes a thermocouple extending along a transverse axis. The thermocouple is interposed between the first and second ducts which are shaped in such a way that the thermocouple undergoes a compressive stress, in the transverse direction.

### BACKGROUND OF THE INVENTION

The invention relates to a thermoelectric device designed to generate an electric current, in particular by using exhaust gases discharged by a combustion engine.

The invention also relates to a manufacturing method of such a thermoelectric device.

### STATE OF THE ART

A conventional architecture of a thermoelectric generator uses thermoelectric modules subjected to a temperature gradient between two of their opposite surfaces. Such thermoelectric modules generally comprise thermocouples electrically connected in series and thermally connected in parallel. Each thermocouple is formed by two legs connected to one another at one of their ends by an electric connecting element. The legs forming a thermocouple are made from different thermoelectric materials designed to generate an electric current when they are subjected to a temperature gradient. The thermocouples are electrically connected in series by electric connecting elements which are generally metallic elements.

Furthermore, the temperature gradient is created by arranging two heat sources on the opposite surfaces of the thermoelectric modules, a first source called cold source and a second source called hot source. Each of the two sources can comprise a duct in which a fluid flows, the fluid associated with the cold source having a lower temperature than that of the fluid associated with the hot source.

Such devices can be used in astute manner in heat exchangers to produce electricity. In particular, this type of device can be associated with a combustion engine, converting heat originating from the exhaust gases of the engine.

However, these thermoelectric generators can suffer from the appearance of thermal resistances between the thermoelectric modules and the heat sources. Indeed, under certain operating conditions, the thermoelectric modules can be subjected, in cyclic manner, to strong thermal gradients, in particular when the hot source is generated by heat originating from exhaust gases.

The difference between the thermal expansion coefficients of the materials of the thermoelectric modules and the materials forming the heat sources is the cause of large mechanical stresses and strains generated by the numerous thermal cycles when the thermoelectric generator is in operation. These thermo-mechanical strains can impair the quality of the thermal contacts between the heat sources and the thermoelectric modules, which can have detrimental consequences on the thermal and electrical performances of the thermoelectric generator, but also on its thermo-mechanical reliability and longevity.

### OBJECT OF THE INVENTION

In the field of electric power generation, a requirement exists to provide a thermoelectric generator taking advantage of its thermal environment while at the same time being reliable, efficient, and easy to manufacture.

This requirement tends to be met by providing a thermoelectric generator comprising:
a calendar extending along a longitudinal axis and provided with two plates each comprising a pass-through opening and respectively located at two opposite ends of the calendar in the longitudinal direction;
two additional plates each comprising a circulation opening and arranged in such a way that the calendar is located between the two additional plates;
a first duct arranged in a second duct, the first and second ducts being disposed in the calendar and extending along a longitudinal axis and each comprising two opposite ends in the longitudinal direction;
a thermocouple fitted between the first and second ducts.

The first duct of said generator is assembled in tightly sealed manner on the two additional plates so that each of the ends of the first duct communicates with the circulation opening formed in one of the additional plates. Furthermore, the second duct is assembled on the two plates in such a way that each of the ends of the second duct communicates with the opening of one of the plates and that the assembly formed by the second duct and the calendar is tightly sealed.

According to a first embodiment, one of the two plates of the calendar is secured in tightly sealed manner with one of the two additional plates so as to delineate an inter-plate space communicating with a sealed internal space delineated by the second duct via at least the opening formed in the plate of the calendar. According to this embodiment, the device also comprises an outlet pipe formed in one of the secured plates and communicating with the inter-plate space.

Preferentially, the device comprises means for creating a vacuum in the inter-plate space and the internal space via the outlet pipe. In advantageous manner, the inter-plate space and the internal space comprise an inert gas.

According to another embodiment, the thermocouple extends in a transverse direction, and the first and second ducts are shaped in such a way that the thermocouple undergoes a compressive stress, in the transverse direction, between said first and second ducts.

Advantageously, the distance d1 separating the first and second ducts at the level of the cross-section of the thermocouple is smaller than the transverse dimension d2 of the thermocouple, the distance d1 and dimension d2 being measured at the same temperature.

According to one embodiment, the thermoelectric generator comprises circulation means of a first fluid at a first temperature in the first duct, and of a second fluid covering the second duct, the second fluid being at a second temperature lower than the first temperature.

In advantageous manner, the fluid circulation means are configured to make a pressurized fluid flow in the first duct and/or in the second duct.

A method for producing this type of thermoelectric generator is also provided comprising the following steps:
providing the first and second ducts, the first duct being configured to be housed in the second duct and to extend along the longitudinal axis of the second duct;
providing the thermocouple extending along the transverse axis;
assembling the first and second ducts so that the temperature of the first duct and/or of the thermocouple is lower than the temperature of the second duct when assembly of the first and second ducts and of the thermocouple is performed to form the thermoelectric device so that the thermocouple is subjected to a compressive stress, in the transverse direction, between the first and second ducts.

According to a particular mode of implementation, the method for producing this type of thermoelectric generator comprises the following steps:
providing first and second half-ducts extending in the longitudinal direction and configured to form the second duct by assembling the first and second half-ducts;
arranging the first and second half-ducts facing one another so that the first duct is housed between the two half-ducts, and the thermocouple is located between the first half-duct and the first duct;
pressing the first and second half-ducts towards one another so as to impose a compressive stress on the thermocouple, in the transverse direction, between the first half-duct and the first duct;
securing the first and second half-ducts to one another to form the second duct, the thermocouple being kept in compression in the transverse direction, between the first and second ducts.

In advantageous manner, the first and second ducts respectively comprise substantially flat and parallel first and second surfaces, arranged facing one another so that the thermocouple is located between said first and second surfaces.

Preferentially, an interface strip made from electrically insulating material is placed between the thermocouple and the first duct, and/or between the thermocouple and the second duct.

A method for generating electric current by the device produced is also provided comprising the following steps:
making a first fluid having a first temperature flow in the first duct;
making a second fluid having a second temperature lower than the first temperature flow around the second duct.

According to a preferred mode of generating an electric current, the device is configured in such a way that exhaust gases discharged by a combustion engine flow either in the first duct or around the second duct.

### BRIEF DESCRIPTION OF THE DRAWINGS

Other advantages and features will become more clearly apparent from the following description of particular embodiments of the invention given for non-restrictive example purposes only and represented in the appended drawings, in which:

FIGS. 1, 3 and 4 schematically illustrate a thermoelectric device according to different embodiments of the invention, in transverse cross-section;

FIG. 2 schematically illustrates the device of FIG. 1, in longitudinal cross-section;

FIGS. 5 to 7 schematically illustrate different steps of a method for producing a thermoelectric device according to an embodiment of the invention, in transverse cross-section;

FIG. 8 schematically illustrates an exploded view of a thermoelectric device comprising a calendar according to an embodiment of the invention;

FIG. 9 schematically illustrates a thermoelectric device comprising a calendar according to an embodiment of the invention, in longitudinal cross-section.

### DESCRIPTION OF PREFERRED EMBODIMENTS

To enable operation of a thermoelectric generator to be improved, it is preferable to pay particular attention to the thermal and electric connections disposed inside the generator. It is therefore advantageous to pay particular care to the quality of the contacts between the heat sources and the thermoelectric module of the generator. In order to produce such a thermoelectric generator, an advantageous arrangement and assembly of certain components forming the thermoelectric generator is envisaged.

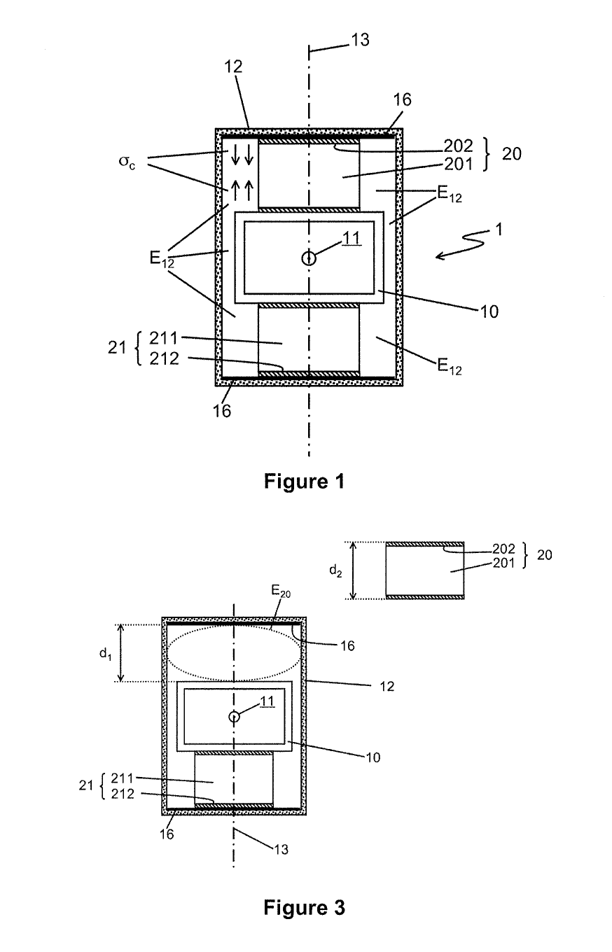

According to an embodiment illustrated in FIG. 1, a thermoelectric device 1 comprises a first duct 10 and a second duct 12 extending along a longitudinal axis 11. The first duct 10 is located in the second duct 12. In other words, the first and second ducts 10 and 12 are arranged in such a way that they extend along the longitudinal axis 11, for example in parallel manner and advantageously in coaxial manner.

The thermoelectric device 1 further comprises a thermocouple 20 preferentially extending along a transverse axis 13, perpendicular or substantially perpendicular to the longitudinal axis 11. The thermocouple 20 is fitted between the first duct 10 and second duct 12. In preferential manner, the ducts 10 and 12 are shaped in such a way that the thermocouple 20 undergoes a certain compressive stress σ_{c}, along the transverse axis 13. The compressive stress σ_{c} is a clamping stress which is applied in permanent manner to the thermocouple 20, between the first duct 10 and second duct 12, and it is preferably comprised between 0.2 and 10 MPa, advantageously between 0.5 and 4 MPa.

In preferential manner, the thermoelectric device 1 also comprises an additional thermocouple 21 also located between the first duct 10 and second duct 12. The thermocouple 20 and the additional thermocouple 21 are for example arranged on each side of the transverse axis 13 of the first duct 10. According to this preferential configuration, the thermoelectric device comprises a stack, along the transverse axis 13, comprising the thermocouple 20 fitted on the first duct 10, itself arranged on the additional thermocouple 21. This stack is disposed inside the second duct 12 so that the thermocouples 20 and 21 are located between the first duct 10 and second duct 12. In other words, the first duct 10 is kept at a distance from the second duct 12 by means of the thermocouples 20 and 21.

In the following, a thermocouple is defined as being an element comprising two legs electrically connected to one another, preferably at one of their ends, by an electrically conducting connecting element, which is also preferably thermally conducting. The legs of any one thermocouple are formed from two materials of different thermoelectric natures. What is meant by materials of different thermoelectric natures is materials of different chemical compositions able, when they are electrically connected, to transform thermal energy into electric power and/or vice versa. For example, it is possible to use a single semiconductor material having different types of doping.

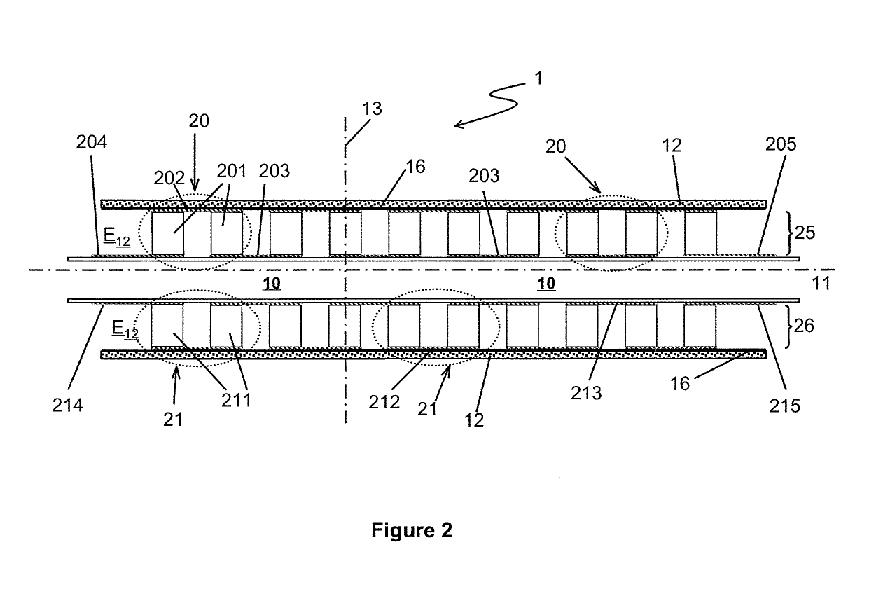

As illustrated in FIG. 2, the thermoelectric device 1 in advantageous manner comprises several thermocouples electrically connected to one another in series by connecting elements 203 to form a first thermoelectric module 25 fitted between the first duct 10 and second duct 12. The module 25 preferentially comprises identical thermocouples 20, also subjected to compressive stresses σ_{c} between the first duct 10 and second duct 12.

Electric termination connectors 204 and 205 are located at the ends of the series of thermocouples 20 of the module 25 to form the electric connections of the thermoelectric module 25. The connectors 204 and 205 can be used in particular to collect the electric current generated by the module 25, or to connect the module 25 with other thermoelectric modules.

Preferentially, the thermoelectric device 1 also comprises an additional thermoelectric module 26 comprising the additional thermocouple 21, also located between the first duct 10 and second duct 12. In a preferential configuration, the thermoelectric device 1 comprises a stack, along the transverse axis 13, comprising the thermoelectric module 25 fitted on the first duct 10, itself fitted on the additional module 26. This stack is located inside the second duct 12 so that the modules 25 and 26 are interposed between the first duct 10 and second duct 12.

In the same way as for the module 25, module 26 preferably comprises a plurality of thermocouples 21 connected to one another in series by connecting elements 213, and electric terminal connectors 214 and 215. The number of thermocouples forming the modules 25 and 26 can be evaluated in terms of the best possible trade-off between the geometry of the thermocouples, their distributions and the electric power produced from the thermal power passing through the thermocouples.

The thermoelectric device 1 is configured to generate an electric power from a heat transfer between the thermocouple 20 and two heat sources generating a thermal gradient.

The thermocouple 20 (21) comprises two legs 201 (211) made from different thermoelectric materials connected to one another by an electrically conducting element 202 (212). The two legs 201 (211) can be made from semiconductor material, such as silicon or silicon-germanium alloy, respectively P-doped and N-doped. The legs 201 (211) can also be made from semi-metals (Bi, Sb, etc.). In fact, the person skilled in the art is able to choose the type of material of the legs of the thermocouple 20 (21) according to the environment in which the thermoelectric device is to be used.

The legs 201 (211) can have any geometric shape, for example a parallelepiped or cylindrical shape. Each leg 201 (211) extends along the transverse axis 13 so that it is located between the first duct 10 and second duct 12. In addition, each leg 201 (211) has first and second ends located in opposite manner in the transverse direction 13. The first end is located between the first duct 10 and the second end, which is itself located between the second duct 12 and the first end. Each leg 201 (211) of the thermocouple 20 (21) comprises at its first end connecting elements 203 (213) or electric termination connectors 204 (214) and 205 (215) forming a first end of the thermocouple 20 (21).

Furthermore, the legs 201 (211) of the thermocouple 20 (21) are connected to one another, preferably at the second end, by the electrically conducting element 202 (212) generally formed by a metallic element. The element 202 (212) then forms the second end of the thermocouple 20 (21), opposite the first end, in the transverse direction 13.

The heat sources of the thermoelectric device 1 are provided with a first duct 10 and a second duct 12 and are configured to create a thermal gradient between the opposite ends of the thermocouple 20. The first duct 10 is advantageously a tightly sealed duct configured to enable circulation of a first fluid.

The first duct 10 preferably comprises internal fins to improve the heat exchange between the first fluid and the internal walls of the first duct 10. The second duct 12 is advantageously a tightly sealed duct configured to be sunk in a second fluid, so that the first duct 10 is devoid of any contact with the second fluid, or to limit the contact between the two fluids. The first duct 10 and second duct 12 are in particular made from stainless steel, and can be formed by any known means, for example by profiling, welding and/or brazing.

In order to facilitate heat transfer between the heat sources and the thermocouple 20, the first and second ends of the thermocouple 20 are preferentially in direct contact respectively with the first duct 10 and second duct 12. Furthermore, to enable the thermoelectric device 1 to generate an electric power, the contacts between the ducts 10 and 12 and the thermocouple 20 have to avoid creation of short-circuits within the thermocouple 20 or of the thermoelectric module 25 while at the same time facilitating heat transfers. Thus, the parts of the ducts 10 and 12 and/or of the thermocouple 20 which constitute these contacts are made from an electrically insulating and thermally conducting material.

In preferential manner, the contacts between the thermocouple 20 and the heat sources comprise a layer made from an electrically insulating material. This layer can be made from silicon oxide or from a material of ceramic type, for example from aluminas (Al₂O₃) which have undergone hard anodization, Ceramaze®, Keronite®, or from alumina with or without titanium dioxide. The layer can also be made from a material of vitroceramic type such as chromium oxide. Furthermore, the parts in contact, according to the compatibility of the materials used, are subjected to an anodization step or comprise a DLC coating (DLC standing for Diamond-Like Carbon).

Advantageously, the thermoelectric device 1 comprises an interface strip 16, commonly called substrate, interposed between the second duct 12 and the electrically conducting element 202, i.e. the second end of the thermocouple 20. The strip 16 can be made from AlN and is in direct contact with the thermocouple 20 and/or the second duct 12.

Preferentially, the thermoelectric device 1 also comprises the same type of interface strip 16 interposed between the first duct 10 and the first end of the thermocouple 20. This type of interface strip 16 advantageously performs protection of the thermocouple 20 against the occurrence of a short-circuit. Furthermore, the interface strip 16 can also perform a function of mechanical buffer to homogenize the clamping stresses applied on the thermocouple 20 by the ducts 10 and 12 when assembly is performed, and possibly during operation of the thermoelectric device 1. Furthermore, this type of interface strip 16 advantageously enables a thermal homogenization between the ends of the thermocouple 20 and the first duct 10 and second duct 12. The thermoelectric device 1 described above enables the thermocouple 20 to be located between two heat exchange walls formed by the ducts 10 and 12. The thermocouple 20 is subjected to a compressive stress σ_{c} applied by the first duct 10 and second duct 12, advantageously enabling a continuous clamping stress to be ensured in the transverse direction 13.

This clamping stress prevents or at least minimizes the effect of the thermomechanical strains of the ducts 10 and 12 and/or of the thermocouple 20 on the impairment of the contact areas between these elements. The compressive stress σ_{c} thus enables high-quality contacts to be preserved between the heat sources and the thermocouple 20, which prevents the creation of thermal resistances in the heat transfer areas. The thermal resistances are then minimized and the heat transfer is improved. The compressive stress σ_{c} thereby advantageously improves the conversion of thermal energy passing through the thermocouple into electric power.

The compressive stress σ_{c} furthermore advantageously limits the shearing stresses which are detrimental to the thermoelectric legs 201 of the thermocouple 20.

As illustrated in FIG. 3, the distance d1 separating the first duct 10 and second duct 12 at the level of the transverse cross-section of the thermocouple 20 is smaller than the transverse dimension d2 of the thermocouple 20. The distance d1 and the dimension d2 are measured at the same temperature Tmes. The first duct 10 and second duct 12 do in fact define a space E20 configured to accommodate the thermocouple 20, and the distance d1 corresponds to the transverse dimension of this space E20. Under identical thermal and mechanical conditions, the transverse dimension d2 of the thermocouple 20 is larger than the transverse dimension d1 of the space E20.

Manufacture of the thermoelectric device 1 can be performed in several manners, in particular by using the difference of the thermomechanical strains of the ducts 10 and 12 and of the thermocouple 20. Thus, and for example purposes, the temperatures of the thermocouple 20 and of the ducts 10 and 12 can be adjusted when the device 1 is manufactured so that the thermocouple 20 can be housed in the space E20. On return to thermal equilibrium, in other words the ducts 10 and 12 and thermocouple 20 are for example at the same temperature, the thermocouple 20 is then subjected to a compressive stress, in the transverse direction 13, applied between the first duct 10 and second duct 12. The materials of the ducts 10 and 12 are chosen such as to be sufficiently rigid to subject the thermocouple 20 to said compressive stress at thermal equilibrium.

In the particular embodiment which follows, the thermoelectric device 1 comprises circulation means (not represented in the figures) for flow of fluids in the device 1. These means are configured to make a first fluid flow at a first temperature T1 in the first duct 10. The circulation means are also configured to make a second fluid flow covering the second duct 12, the second fluid being at a second temperature T2 which is preferably lower than the first temperature T1. Furthermore the fluid circulation means can be configured to make a pressurised fluid flow in the duct 10 and/or duct 12, thereby increasing the compressive stress σ_{c} applied to the thermocouple 20.

Advantageously, the first temperature T1 is chosen in such a way that the first duct dilates, and/or the second temperature T2 is chosen in such a way that the second duct 12 contracts. The thermomechanical strains of the ducts 10 and 12 produced by the choice of the first T1 and second T2 temperatures further reduce the transverse dimension of the space E20, thereby accentuating the compressive stress σ_{c} undergone by the thermocouple 20. A thermal contact of good quality between the thermocouple 20 and the ducts 10 and 12 can thus be guaranteed.

The circulation means of the first and second fluids can for example comprise a pump configured to make a coolant liquid flow in a calendar comprising the second duct 12. Furthermore, the circulation means can comprise a set of ducts configured to transport and make exhaust gases discharged by a combustion engine flow in the first duct 10. The temperatures of the exhaust gases and of the coolant liquid are different and can generate a large thermal gradient at the ends of the thermocouple 20, in the transverse direction 13.

From an electrical reliability standpoint, the metallic connections of conventional thermoelectric generators may suffer from an oxidation problem, especially when they are subjected to high temperatures, which is often the case for this type of thermoelectric device. Furthermore, this oxidation is accentuated when these metallic connections are located in an atmosphere comprising corrosive residues such as an atmosphere containing combustion engine exhaust gases.

According to a preferred embodiment, the first duct 10 and second duct 12 delineate a tightly sealed internal space E₁₂. Advantageously, the thermoelectric device 1 comprises means for creating a vacuum in the internal space E₁₂. Furthermore, the thermoelectric device 1 can advantageously comprise means for quenching the internal space E₁₂ with an inert gas such as argon, helium or nitrogen.

Creation of a vacuum or inlet of an inert gas in the internal space E₁₂ advantageously protects the components forming the thermocouple 20 against oxidation, in particular the electrically conducting element 202, the connecting elements 203 or the terminal connectors 204 and 205, which are generally made from metallic materials which easily oxidize. Furthermore, when the thermoelectric device 1 is configured to operate in an environment containing exhaust gases, which is a corrosive environment, the risk of oxidation of the components of the thermoelectric device 1 is greater.

This preferential embodiment also enables the outer walls of the first duct 10 and the inner walls of the second duct 12 to be protected against oxidation, thereby improving the reliability of the device 1 from a thermal and electric point of view.

The method for manufacturing a thermoelectric device as defined above comprises the following steps:
providing the first duct 10 and second duct 12, the first duct 10 being configured to be housed in the second duct 12 and to extend along the longitudinal axis 11 of the second duct 12;
providing the thermocouple 20 extending along the transverse axis 13.

Furthermore, the manufacturing method comprises a step where the first and second ducts 10 and 12 are assembled so that the thermocouple 20 undergoes a compressive stress σ_{c}, in the transverse direction 13, between the first duct 10 and second duct 12. When assembly is performed, the thermocouple 20 is fitted between the ducts 10 and 12 and is subjected to the compressive stress σ_{c} applied by the ducts 10 and 12.

Preferentially, the compressive stress σ_{c} is a permanent clamping stress in the transverse direction 13. What is meant by clamping stress is a stress enabling the thermocouple 20 to be fixed and immobilized with respect to the ducts 10 and 12, in particular in the transverse direction 13. The shearing stresses within the thermocouple 20 are thereby limited. Attenuating the effect of this type of stresses advantageously enables deterioration and the risk of breaking of the thermoelectric legs of the thermocouple 20 to be limited.

Application of a compressive stress σ_{c} when assembly of the components of the thermoelectric device 1 is performed can be achieved by any known means in the field of assembly of mechanical parts. For example, the thermoelectric device 1 can comprise clamping means configured to reduce the dimension of the second duct 12 in the transverse direction 13.

The thermoelectric device 1 can thus comprise clamping components such as a clamping ring (not represented in the figures) of the second duct 12. When assembly is performed, the clamping ring can be fitted in such a way as to envelop the second duct 12, a part of the wall of which is thus interposed between a wall of the clamping ring and the thermocouple 20. The ring is then tightened so as to apply the compressive stress σ_{c} on the thermocouple 20 between the first 10 and second duct 12.

The clamping means in fact enable the opposite walls of the second duct 12 to be pressed towards one another in the transverse direction 13. Furthermore, the first duct 10 and thermocouple 20 are arranged inside the second duct 12 so that the thermocouple 20 is interposed between the first duct 10 and second duct 12, in the transverse direction 13. The ducts 10 and 12 and thermocouple 20 are arranged so that the clamping means enable the first duct 10 to be pressed towards the second duct 12 so that the thermocouple 20 undergoes the compressive stress σ_{c}.

In the thermoelectric device 1, the ducts 10 and 12 are configured to form the heat sources associated with the thermocouple 20. To obtain an efficient thermal behavior, the heat sources are preferably thermally insulated from one another or located as far as possible away from one another.

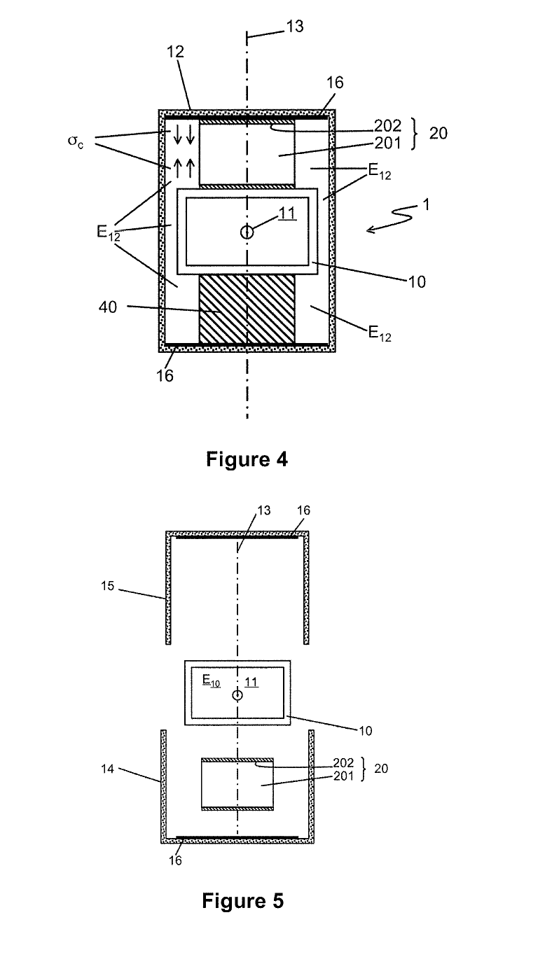

As illustrated in FIG. 4, the first duct 10 is provided with a first wall separated from the second duct 12 by the thermocouple 20, and with a second wall opposite the first wall, in the transverse direction 13. For reasons of thermal and mechanical considerations, a wedge 40 preferably made from non-compressible and thermally insulating material, is fitted between the second wall of the first duct 10 and the second duct 12.

Advantageously, the manufacturing method provides for an additional thermocouple 21, preferably symmetrical to the thermocouple 20 with respect to the first duct 10. The additional thermocouple 21 is arranged between the second wall of the first duct 10 and the second duct 12. The clamping means thus enable a compressive stress to be applied both to the thermocouple 20 and to the additional thermocouple 21. Furthermore, this advantageous arrangement both enables the heat sources (ducts 10 and 12) to be separated from one another and a second electric power generation source to be provided (additional thermocouple 21) for a better use of the thermal gradient provided by the heat sources.

According to a particular embodiment, an interface strip 16 made from electrically insulating material is fitted between the thermocouple 20 and the first duct 10, and/or between the thermocouple 20 and the second duct 12. The interface strip 16 can be made from AlN, and it is arranged so as to be in direct contact with the thermocouple 20, and/or the ducts 10 and 12. The strip 16 advantageously prevents the occurrence of a short-circuit in the thermocouple 20 and enables the compressive stresses applied to the thermocouple 20 by the first 10 and second 20 ducts to be homogenized.

According to a particular implementation, the manufacturing method comprises an assembly step in which the assembly temperature Ta1 of the first duct 10 and/or of the thermocouple 20 is lower than the assembly temperature Ta2 of the second duct 12. During this assembly step, the thermocouple 20 is arranged so as to be in contact with the two heat sources. What is meant by contact with a heat source is that the thermocouple 20 is in direct contact either with the duct associated with said heat source (10 or 12) or with the interface strip 16 which is itself in direct contact with said duct (10 or 12).

Preferentially, the assembly temperature Ta1 of the first duct 10 and/or of the thermocouple 20 is chosen so as to be lower than and advantageously considerably lower than the temperature of the heat source comprising the first duct 10 when the thermoelectric device 1 is operational and generates electric power. In the same way, the assembly temperature Ta2 of the second duct 12 is chosen so as to be higher than, and advantageously considerably higher than, the temperature of the heat source comprising the second duct 12 when the thermoelectric device 1 is operational and generates electric power.

The assembly step described above advantageously generates thermomechanical strains of the ducts 10 and 12 which enable an increase or an application of the compressive stress σ_{c} undergone by the thermocouple 20. Indeed, after the assembly step, and when the thermoelectric device 1 is subjected to the temperature gradient created by the heat sources, the first duct 10 dilates, whereas the second duct 12 contracts, further compressing the thermocouple 20 fitted between the two ducts 10 and 12.

According to a preferred embodiment illustrated in FIGS. 5 to 7, the production method of the thermoelectric device 1 uses assembly of two half-ducts to form the second duct 12. First 14 and second 15 half-ducts extending along the longitudinal axis 11 are in fact used. The two half-ducts 14 and 15 are configured to form the second duct 12, in tight manner, when they are assembled. The two half-ducts 14 and 15 can for example have complementary concave shapes configured so as to compose the shape of the second duct 12.

The first 14 and second 15 half-ducts are then arranged facing one another, disposing the first duct 10 and the thermocouple 20 between the first 14 and second 15 half-ducts. Furthermore fitting the half-ducts 14 and 15 facing one another is performed in such a way that the thermocouple 20 is interposed between the first half-duct 14 and the first duct 10.

Then the first 14 and second 15 half-ducts are pressed towards one another by applying a pressure P on the two half-ducts 14 and 15. This step enables the pressure P exerted between the first 14 and second 15 half-ducts to be transferred to the thermocouple 20. This step is thus performed to impose and apply a compressive stress on the thermocouple 20, in the transverse direction 13, between the first half-duct 14 and the first duct 10.

In order to conserve the compressive stress imposed on the thermocouple 20, the first and second half-ducts 14 and 15 are subsequently secured to one another to form the second duct 12. The first duct 10 delineates an internal space E₁₀, and the assembled duct 12 delineates a totally independent internal space E₁₂ tightly sealed with respect to the internal space E₁₀ of the first duct 10.

Securing of the two half-ducts 14 and 15 to one another is performed in tight manner in particular by longitudinal fillet welds Sc, or any other known means. What is meant by longitudinal fillet weld is a longitudinal overlap seal enabling the two half-ducts 14 and 15 to be joined to one another while ensuring the continuity of the material, thereby ensuring the tightness of the formed second duct 12. This securing is performed in such a way that the thermocouple 20 is kept in compression, in the transverse direction 13, between the first duct 10 and the first half-duct 14, i.e. the second duct 12.

According to a preferred embodiment, the first and second ducts 10, 12 respectively comprise first 101 and second 121 surfaces arranged facing one another so that the thermocouple 20 is located between said first 101 and second 121 surfaces. The first 101 and second 121 surfaces can have a convex shape. The thermocouple 20 is then arranged between the convex surfaces 101 and 121 which procure a spring effect when the pressure P is transferred to the thermocouple 20. This advantageously enables the stress applied to the thermocouple 20 to be homogenized.

Advantageously, the first 101 and second 121 surfaces are substantially flat and parallel. The particular shape of the first and second ducts 10 and 12 advantageously facilitates assembly of the thermocouple 20 and arrangement of the latter between these two ducts. It also enables a better distribution of the clamping stress and a reduction of the thermal contact resistance to be obtained.

Furthermore, disposing the thermocouple 20 between the flat surfaces advantageously enables the pressure P applied on the two half-ducts 14 and 15 to be transferred easily and efficiently to the thermocouple 20 arranged between the two ducts 10 and 12. The thermocouple 20 thus undergoes a compressive stress σ_{c} applied by the first and second ducts 10 and 12.

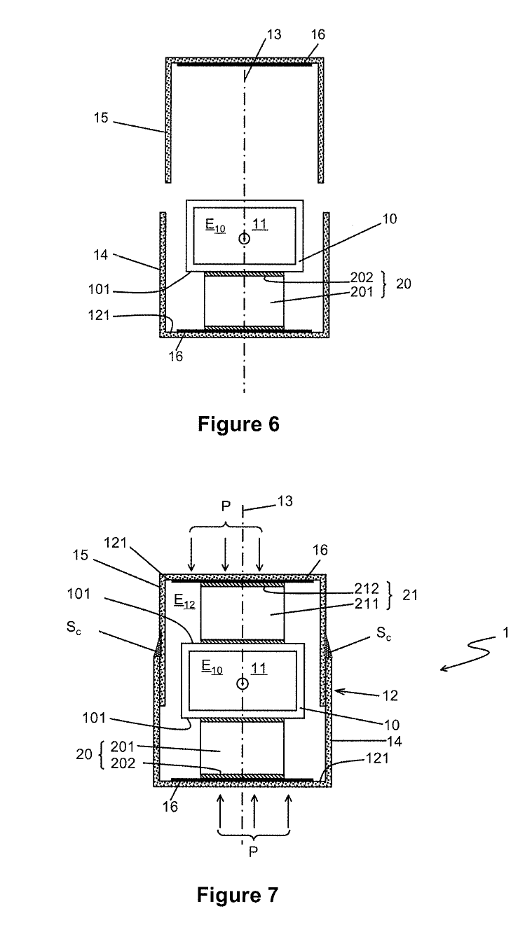

For example purposes, the half-ducts 14 and 15 can advantageously have a U-shaped transverse cross-section (FIG. 5). Thus, each half-duct 14 and 15 comprises two lateral surfaces joined by a central surface. When assembly is performed, the thermocouple 20 can be disposed on the central surface 121 of the first half-duct 14 (FIG. 6). Furthermore, the first duct 10 preferentially has a parallelepiped shape so that it has a flat surface 101.

The first duct 10 is then arranged on the thermocouple 20 so that the flat surface 101 is parallel to the central surface 121 of the first half-duct 14. In other words, the thermocouple 20 is interposed between the central surface 121 and the flat surface 101 (FIG. 6).

To form the second duct 12, the second half-duct 15 is, in a first stage, arranged facing the first half-duct 14, more particularly facing the stack successively comprising the first half-duct 14, the thermocouple 20 and the first duct 10 (FIG. 7). The second duct 12 thus forms the internal space E₁₂, totally independent from the internal space E₁₀ of the first duct 10.

Furthermore, to take account of thermal and/or mechanical considerations, a wedge 40 can be fitted between the first duct 10 and the second duct 12 (FIG. 4). The wedge 40 and thermocouple 20 are arranged on each side of the first duct 10, in the transverse direction 13. The wedge 40 is preferentially made from non-compressible and thermally insulating material. The wedge thus enables the pressure applied on the two half-ducts 14 and 15 to be efficiently transferred to the thermocouple 20. Furthermore, the wedge 40 also enables the heat sources to be thermally insulated from the thermo0electric device 1.

Advantageously, the wedge is formed by an additional thermocouple 21 (FIG. 7). From an electric point of view, this arrangement advantageously enables a second electric power generation source to be provided for a better use of the thermal gradient created by the first duct 10 and second duct 12. From a thermal point of view, this arrangement further enables the ducts 10 and 12 to be located away from one another, to minimize the mutual thermal influence of the two heat sources of the thermoelectric device 1.

According to a preferred embodiment, the use of a calendar is scheduled comprising a bundle of ducts of the same type as the second duct 12. What is meant by calendar is a cavity preferably having a cylindrical shape, delineated by a hollow body. A calendar enables circulation of a given fluid around a duct, or a bundle of ducts, housed in the calendar, thus forming one of the two heat sources of the thermoelectric device.

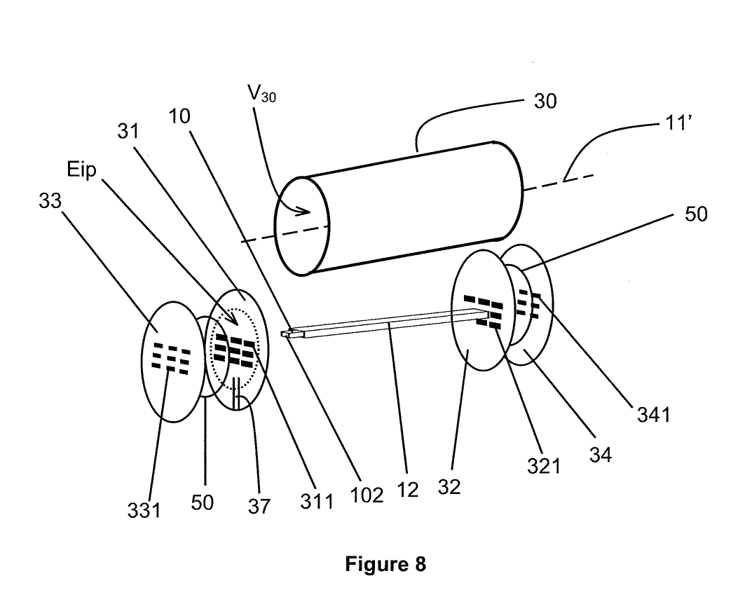

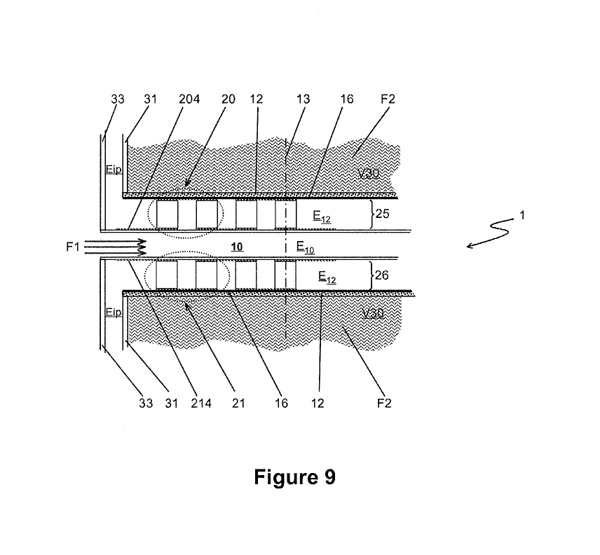

As illustrated in FIGS. 8 and 9, the method provides for the use of a calendar 30 extending along a longitudinal axis 11′. Preferentially, the longitudinal axis 11′ of the calendar is parallel to the longitudinal axis 11 of the ducts 10 and 12. The calendar 30 is provided with two plates 31 and 32 respectively arranged at the two opposite ends of the calendar 30 in the direction of the longitudinal axis 11′.

The calendar 30 and the second duct 12, or the bundle of ducts 12, delineate a calendar volume V30 totally independent from the internal space E₁₂ of each duct 12. The calendar 30 can further comprise an inlet and an outlet configured to make a fluid, preferably a heat transfer fluid, flow in the cavity of the calendar 30 around the second duct 12. The fluid flowing in the calendar 30 is in contact with the external walls of the second duct 12, or of the bundle of ducts 12.

In preferential manner, the calendar 30 has a cylindrical shape the two plates 31 and 32 of which form the bases. Furthermore, the plates 31 and 32 each comprise at least one pass-through opening. In FIG. 8, the plate 31 comprises opening 311 and the plate 32 comprises opening 321.

The openings 311 and 321 are drilled in the plates 31 and 32 so as to be able to accommodate the second duct 12. In fact, the second duct 12 comprises two longitudinal ends 122 and 123, in other words opposite ends in the direction of the longitudinal axis 11 of the ducts 10 and 12. Each of the ends communicates with the opening (311 or 321) formed in one of said plates (31 or 32). The assembly formed by the second duct 12 and calendar 30 is moreover assembled and secured in tightly sealed manner.

Preferentially, the duct 12 is disposed so as to be substantially parallel to the longitudinal axis 11′ of the calendar. Furthermore, the duct 12 can also be arranged in the calendar 30, between the plates 31 and 32, in any direction, for example inclined or curved.

For example, each of the ends (122 or 123) is configured to be engaged in the opening (311 or 321) of one of the two plates 31 and 32. The ends of the second duct 12 are then secured in tightly sealed manner to the plates 31 and 32 of the calendar 30, in particular by brazing, welding, or any other known means.

The second duct 12 is thus disposed between the plates 31 and 32 of the calendar 30. The sealed internal space E₁₂ of the second duct 12 is accessible only via the two openings 311 and 321 respectively formed in the plates 31 and 32, which are commonly called “tubular plates” of the calendar 30. In addition, this internal space E₁₂ is totally independent from the volume V30 of the calendar 30. In the same manner as for a single second duct 12, a bundle of preferably identical ducts 12 can advantageously be assembled between these two plates 31 and 32.

In advantageous manner, the method also uses a bundle of ducts of the same type as the first duct 10. According to a particular implementation mode, the use of two additional plates is scheduled.

As illustrated in FIG. 8, two additional plates 33 and 34 are provided each comprising at least one pass-through circulation opening 331 and 341. The circulation openings 331 and 341 are drilled in the additional plates 33 and 34 so as to receive the first duct 10. Furthermore, the calendar 30 is interposed between the two additional plates 33 and 34. The first duct 10, comprising two opposite longitudinal ends 102 and 103, is disposed between the two additional plates 33 and 34. Each of the ends 102 and 103 of the first duct 10 communicates with the circulation opening 331 and 341 formed in one of said additional plates 33 and 34.

For example, each of the ends 102 and 103 of the first duct 10 is engaged in the openings 331 and 341 respectively of the two additional plates 33 and 34. These ends are then secured in tightly sealed manner to the additional plates 33 and 34 by any known means. The first duct 10, housed in the second duct 12, thus passes through the calendar 30 without there being any interaction between the internal space E₁₀ of the first duct 10 and the environment of the volume V30 of the calendar 30.

The sealed internal space E₁₀ of the first duct 10 is accessible only via the two openings 331 and 341 respectively formed in the additional plates 33 and 34. The internal space E₁₀ of the first duct 10 is totally independent from the volume V30 of the calendar 30 and from the internal space E₁₂ of the second duct 12. In the same way as for a single first duct 10, a bundle of preferably identical ducts 10 can advantageously be assembled between these two additional plates 33 and 34.

This particular assembly mode advantageously enables the internal spaces E₁₀ of all the ducts 10 to be accessed simultaneously via the two additional plates 33 and 34. The two additional plates 33 and 34 can thus respectively form an inlet and an outlet of a fluid able to flow at the same time in the different ducts 10.

This particular implementation mode enables a heat source to be formed comprising the first duct 10, or a bundle of ducts, configured to make a fluid, preferably a heat transfer fluid, flow. This heat source is advantageously independent from the calendar 30 and therefore from the heat source comprising the second duct 12. The manufacturing method thus advantageously enables a thermoelectric device 1 to be produced arranged so as to comprise several couples of first and second ducts (10 and 12), in other words several thermocouples (20, 21) or thermoelectric modules (25, 26) arranged between two different heat sources. This advantageous arrangement thus enables the electric power generation capacity of the thermoelectric device 1 to be increased.

Advantageously, at the level of one end of the calendar 30, in the direction of the longitudinal axis 11′, a plate of the calendar 31 or 32 is secured in tightly sealed manner with an additional plate 33 or 34. This assembly is performed in such a way that the secured plates form an empty space Eip which will be called inter-plate space.

Preferentially, the plates are secured to one another at the level of their peripheries so that the opening or openings formed in the plate of the calendar (31 or 32) communicate with the inter-plate space Eip and are not blanked off by the additional plate (33 or 34). For example purposes, the inter-plate space Eip can be achieved by spot facing in the thickness of one of the two assembled plates. Securing of the two plates to one another can be achieved by any known means, for example by a weld or by the use of a seal 50 compressed by clamping between the secured plates.

This assembly step thus enables an inter-plate space Eip to be formed communicating with the internal space E12 of the second duct, or of the bundle of ducts 12, via the opening or the openings of the plate (31 or 32) of the calendar 30. The inter-plate space Eip is totally independent from the space of the calendar V30. The inter-plate space Eip is furthermore totally independent from the internal space E₁₀ of the first duct 10 or of the bundle of ducts 10 collected by the additional plate (33 or 34).

Advantageously, an outlet pipe 37 is made in one of the plates between which the inter-plate space Eip is disposed. The outlet pipe 37 is configured so as to communicate with the inter-plate space Eip. The outlet pipe 37 preferentially comprises a valve configured to adjust the opening of the pipe 37, and possibly the flow rate of the fluid in the internal space E₁₂ of the duct 12 or of the bundle of ducts 12 via the inter-plate space Eip.

In order to avoid corrosion problems of the components of the thermoelectric device 1, in particular the ducts 10 and 12 and the components of the thermocouple 20, the internal volume E₁₂ of the second duct 12 is advantageously placed in a vacuum. In other words, a vacuum is created in the internal space E₁₂ of the second duct 12, or of the bundle of ducts 12, via the outlet pipe 37 and the inter-plate space Eip.

Furthermore, the internal volume E₁₂ of the second duct 12 can also be filled with an inert gas—the inter-plate space Eip and the internal space E₁₂ are in an inert atmosphere. In other words, the internal space E₁₂ of the second duct 12, or of the bundle of ducts 12, is filled with an inert gas via the outlet pipe 37 and the inter-plate space Eip. The inert gas can for example be argon, helium or nitrogen.

Use of the thermoelectric device 1 produced in this way preferably comprises circulation of heat transfer fluids respectively in the first duct 10 and around the second duct 12. According to a preferential mode for electric current generation by the thermoelectric device 1 illustrated in FIG. 9, a first fluid F1 having a first temperature T1 is made to flow in the first duct 10. In addition, around the second duct 12, a second fluid F2 having a second temperature T2, preferably lower than the first temperature T1, is made to flow.

In other words, under these conditions, the hot source of the thermoelectric device 1 is represented by the first duct 10 and the cold source is represented by the second duct 12. This particular arrangement of the heat sources advantageously enables the compressive stresses applied to the thermocouple 20 by the first 10 and second 12 ducts to be accentuated, or at least to be conserved.

In fact, when the temperature T1 of the fluid F1 is sufficiently high, for example more than 100° C., generally more than 250° C., the first duct 10, which is generally made from metallic material, tends to dilate. In similar manner, when the temperature T2 of the second fluid F2 is sufficiently low, for example lower than 100° C., the second duct 12 tends to contract.

The thermomechanical strains of the first duct 10 and second duct 12 generated in this way result in application of a pressure on the thermocouple 20 having a direction going from the first duct 10 to the second duct 12. Circulation of the first fluid F1 having the first temperature T1 and/or of the second fluid F2 having the second temperature T2 thus advantageously contributes to increasing the compressive stress initially applied on the thermocouple 20.

In advantageous manner, the thermoelectric device 1 makes use of discharge of the exhaust gases of a combustion engine. In other words, the exhaust gases are used to contribute to the formation of a heat source within the thermoelectric device 1.

The method for generating an electric current can thus comprise a step during which the exhaust gases of the combustion engine are removed so as to flow in the first duct 10. Removal of the exhaust gases can thus contribute in advantageous manner to forming the hot source of the thermoelectric device 1. When a duct, or several ducts 10, is or are collected by the additional plates 33 and 34, the exhaust gases can be directed towards one of these additional plates. The exhaust gases are inlet through one of the additional plates 33 or 34, and then flow in the duct or ducts 10 and are outlet through the other additional plate.

The exhaust gases of the combustion engine can furthermore also be removed so as to flow around the second duct 12. When several ducts 12 are collected by the plates 31 and 32 of the calendar 30, the exhaust gases can be conveyed by an exhaust pipe connected to the inlet of the calendar 30 so as to flow around the duct or ducts 12, and to then be removed via the outlet of the calendar 30.

The thermoelectric device 1 can therefore be installed in an apparatus comprising a combustion engine, for example a vehicle. In general manner, this type of apparatus comprises an alternator driven by said engine to generate electric power. The thermoelectric device 1, generating electric power from conversion of the heat of the exhaust gases, thereby advantageously enables the fuel consumption of the engine to be reduced, replacing the alternator in definitive or provisional manner.

1.-15. (canceled)

16. A thermoelectric device comprising:
a calendar extending along a longitudinal axis and provided with two plates each comprising a pass-through opening and respectively arranged at two opposite ends of the calendar in the direction of the longitudinal axis;
two additional plates each comprising a circulation opening and arranged in such a way that the calendar is interposed between the two additional plates;
a first duct arranged in second duct, the first and second ducts being arranged in the calendar and extending along a longitudinal axis and each comprising opposite two ends in the direction of the longitudinal axis;
a thermocouple fitted between the first and second ducts;
wherein the second duct being assembled on the two plates so that each of the ends of the second duct communicates with the opening of one of the plates and the assembly formed by the second duct and calendar is tightly sealed; and
wherein the first duct being assembled in tightly sealed manner on the two additional plates so that each of the ends of the first duct communicates with the circulation opening formed in one of the additional plates.

17. The device according to claim 16, wherein the two plates of the calendar is secured in tightly sealed manner with one of the two additional plates so as to delineate an inter-plate space communicating with an internal space delineated by the second duct via at least the pass-through opening formed in the plate of the calendar, and wherein an outlet pipe is formed in one of the secured plate or the secured additional plate, and communicates with the inter-plate space.

18. The device according to claim 17, comprising at least one pump configured so as to create a vacuum in the inter-plate space and the internal space via the outlet pipe.

19. The device according to claim 17, wherein the inter-plate space and the internal space delineated by the second duct are in an inert atmosphere.

20. The device according to claim 16, wherein the thermocouple extends along a transverse axis, and wherein the first duct and second duct are shaped in such a way that the thermocouple undergoes a compressive stress σ_{c} in the transverse direction between the first duct and the second duct.

21. The device according to claim 20, wherein the distance d1 separating the first duct and the second duct at the level of the transverse cross-section of the thermocouple is smaller than the transverse dimension d2 of the thermocouple, the distance d1 and the dimension d2 being measured at the same temperature.

22. The device according to claim 16, comprising a pumping system for circulating a first fluid at a first temperature T1 in the first duct, and a second fluid covering the second duct, the second fluid being at a second temperature T2 lower than the first temperature T1.

23. The device according to claim 22, wherein the pumping system is configured to make a pressurized fluid flow in the first duct and/or in the second duct.

24. A method for manufacturing a device according to claim 16, comprising the following steps:
providing the first duct and the second duct, the first duct being configured to be housed in the second duct and to extend along the longitudinal axis of the second duct;
providing the thermocouple extending along the longitudinal axis;
wherein the temperature of the first duct and/or of the thermocouple is lower than the temperature of the second duct when assembly of the first and second ducts and of the thermocouple is performed to form the thermoelectric device so that the thermocouple undergoes a compressive stress in the transverse direction between the first and second ducts.

25. The method for manufacturing a device according to claim 24, comprising the following steps:
providing first and second half-ducts extending along the longitudinal axis and configured to form the second duct by assembling the first and second half-ducts;
arranging the first and second half-ducts facing one another so that the first duct is housed between the two half-ducts, and that the thermocouple is interposed between the first half-duct and the first duct;
pressing the first and second half-ducts towards one another so as to impose a compressive stress on the thermocouple, in the transverse direction, between the first half-duct and the first duct;
securing the first and second half-ducts to form the second duct, the thermocouple being kept in compression in the transverse direction between the first and second ducts.

26. The method according to claim 24, wherein the first and second ducts respectively comprise first and second substantially flat and parallel surfaces arranged facing one another so that the thermocouple is interposed between said first and second surfaces.

27. The method according to claim 24, wherein an interface strip made from electrically insulating material is interposed between the thermocouple and the first duct, and/or between the thermocouple and the second duct.

28. A method for generating an electric current by the device according to claim 16, comprising the following steps:
making a first fluid having a first temperature flow in the first duct;
making a second fluid having a second temperature, lower than the first temperature, flow around the second duct.

29. The method for generating an electric current according to claim 28, wherein the first fluid comprises exhaust gases discharged by a thermal engine flow in the first duct.

30. The method for generating an electric current according to claim 28, wherein the second fluid comprises exhaust gases discharged by a thermal engine flow around the second duct.
